(19) United States
(12) Patent Application Publication
(10) Pub. No.: US 2007/0278906 A1
(43) Pub. Date: Dec. 6, 2007

(54) Piezoelectric transformer

(76) Inventors: Heinz Florian, Bad Gams (AT); Alexander Glazunov, Deutschlandsberg (AT); Igor Kartashev, Deutschlandsberg (AT)

Correspondence Address: SLATER & MATSIL, L.L.P., 17950 PRESTON RD, SUITE 1000, DALLAS, TX, 75252-5793, US

(21) Appl. No.: 11/706,859

(22) Filed: Feb. 13, 2007

Related U.S. Application Data
(63) Continuation of application No. PCT/DE05/01383, filed on Aug. 4, 2005.

(30) Foreign Application Priority Data
Aug. 13, 2004 (DE) 10 2004 039 423.7

(51) Int. Cl. H01L 41/107

(52) U.S. Cl. 310/359; 318/116

(57) ABSTRACT

A piezoelectric transformer with a base body containing a piezoelectric material is disclosed. The piezoelectric material is polarized in an input part of the base body along a first axis and in an output part of the base body along a second axis perpendicular to the first axis. In a transition region between the input part and the output part, the polarization of the piezoelectric material gradually changes its direction from a polarization along the first axis to a polarization along the second axis.

This application is a continuation of co-pending International Application No. PCT/DE2005/001383, filed Aug. 4, 2005, which designated the United States and was not published in English, and which is based on German Application No. 10 2004 039 423.7, filed Aug. 13, 2004, both of which applications are incorporated herein by reference.

### TECHNICAL FIELD

The present invention relates generally to a piezoelectric transformer.

### BACKGROUND

Rosen-type piezoelectric transformers are known, e.g., from U.S. Pat. No. 2,974,296. In these transformers, the electric polarization in the ceramic in the input part is directed perpendicular to the polarization in the output part of the transformer.

A problem to be solved is to specify a low-loss piezoelectric transformer.

### SUMMARY

A piezoelectric transformer with a base body is specified, which contains a piezoelectric material that is polarized in an input part of the base body along a first axis and in an output part of the base body along a second axis perpendicular to the first axis. Between the input part and the output part there is a transition region, in which the polarization of the piezoelectric material gradually changes its direction from a polarization along the first axis to a polarization along the second axis.

In the transition region, the direction of electric polarization gradually changes from 0° in the input part up to 90° in the output part. To achieve the gradual change, in one variant the internal electrodes in the input part are divided into two groups, which have different lengths. The difference in the length of the internal electrodes is greater than the thickness of a piezoelectric layer in the input part of the transformer.

A polarized material can be depolarized when the height of the electric input voltage in the transformer exceeds a threshold that corresponds to the coercive electric field of the piezoelectric ceramic. The coercive field is defined as a field strength in which the electric polarization of the piezoelectric ceramic changes its direction.

To prevent the depolarization of the ceramic in the transformer, it is advantageous if the polarity of the input voltage of the transformer (after the polarization process) is the same as the polarity of the electric voltage applied during the polarization process of the transformer. For this purpose, the electric ground of the generator on the input part and the electric ground of the rectifier on the output part are to be connected to the electrodes of the piezoelectric transformer, which were connected to the electric ground during the polarization process.

In one preferred variant, a laminated Rosen-type piezoelectric transformer is specified. The transformer has a base body in the form of a rectangular rod. The base body comprises at least two mechanically interconnected parts, an input part (primary side) and an output part (secondary side).

The input part comprises several piezoelectric layers, which are polarized in the thickness direction. In other words, the polarization is normal to the layers (and parallel to the thickness direction). The polarization may be opposite in two directly adjacent piezoelectric layers as a consequence of the respective connection of the internal electrodes to the external electrodes.

The piezoelectric layers preferably contain ceramic. Between the piezoelectric layers there are first and second internal electrodes. The first internal electrodes are interconnected in a conductive way and form a first group. The second internal electrodes are interconnected in a conductive way and form a second group. The first and second internal electrodes are preferably arranged in an alternating sequence.

The output part is polarized along a longitudinal axis, with an output electrode being arranged, e.g., on the end of the body of the piezoelectric transformer.

The two groups of internal electrodes in the input part have a different distance to the output electrode arranged on the end of the transformer body. This difference is greater than the thickness of an individual ceramic layer in the input part. The group of internal electrodes with a shorter distance to the output electrode is connected in a conductive way to an electric ground during the polarization process.

In one variant, the group of input electrodes with a shorter distance to the output electrode is connected to the ground terminal of a generator, which generates pulses at the input voltage that have the same polarity as the voltage during the polarization process.

The output electrode can be connected to a rectifier such that the DC voltage component of the output voltage has the same polarity as the voltage during the polarization process.

### BRIEF DESCRIPTION OF THE DRAWINGS

Below, the piezoelectric transformer and the arrangement with a piezoelectric transformer are explained with reference to schematic and not-to-scale figures. Shown schematically are:

FIG. 1 provides an example of a Rosen-type multilayer piezoelectric transformer; and

FIG. 2 provides a simplified equivalent circuit diagram of an electric circuit with the piezoelectric transformer according to FIG. 1, which shows the connection of the piezoelectric transformer to the generator and to the rectifier.

### DETAILED DESCRIPTION OF ILLUSTRATIVE EMBODIMENTS

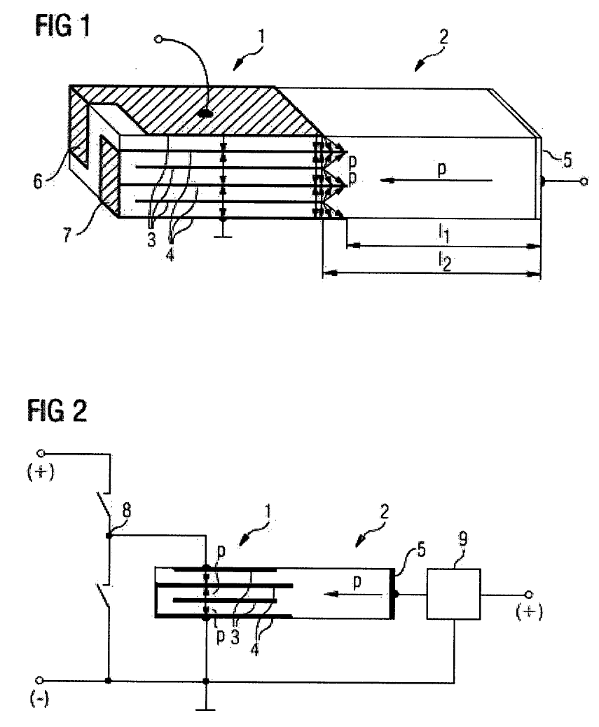

FIG. 1 shows a schematic view of a laminated Rosen-type piezoelectric transformer. The base body of the transformer has two mechanically interconnected parts: the input part 1 and the output part 2.

First internal electrodes 3 connected in parallel to each other by means of a first external electrode 6 are arranged in the input part 1 and second internal electrodes 4 connected in parallel to each other by means of a second external electrode 7. The first internal electrodes 3 form a first group and the second internal electrodes 4 form a second group. The output part 2 has a third external electrode 5, which is arranged on the second end of the output part.

The piezoelectric layers arranged in the input part are polarized along the thickness direction, while the output part is polarized along the length of the transformer body. The arrows specify the directions of electric polarization in the piezoelectric ceramic.

The external electrodes 6 and 7 are arranged on the first end of the transformer body.

The internal electrodes 3 of the first group have a distance L₂ and the internal electrodes 4 of the second group have a distance L₁—in FIG. 1 smaller—to the third external electrode 5, which is different from L₂. The difference between the distances L₁ and L₂ ensure that in this part of the transformer the electric polarization gradually changes its direction from 0°-90° from the input part to the output part. The gradual change in the polarization direction generates mechanical stress at the transition between the input part and the output part, whose magnitude is much smaller than the magnitude of the mechanical stress in a transformer, in which the internal electrodes 3 and 4 have the same distance to the output electrode 5.

FIG. 2 shows the connection of the Rosen-type piezoelectric transformer with an external circuit. The multilayer transformer is depicted by its electrode layers 3 and 4. The internal electrodes 3 and 4 in the multilayer are alternatingly connected to external electrodes 6 and 7, as shown for example in FIG. 1.

The high-voltage output connection of the generator (point 8) is connected to the first internal electrodes 3 of the input part. The second internal electrodes 4 of the input part are connected to the electric ground. The polarity of the pulses of the transformer input voltage is the same as those of the electric voltage during the polarization. The polarity of the output of the rectifier 9, which is connected to the output electrode 5 of the transformer, is also the same as the voltage during the polarization of the output part 2 of the transformer. Such a selection of the polarity of the electrical connections ensures that the piezoelectric ceramic in the transformer is not depolarized when a relatively high input voltage is applied to the transformer.

The description of FIG. 2 provides but one example of an implementation of the structure described herein. This embodiment shows an arrangement/circuit that is appropriate for polarizing the piezoelectric layers as well as for the use of the transformer to transform a first voltage (primary voltage) to a second voltage (secondary voltage). The transformer is adapted to transform AC current. Polarizing is made by connecting a DC voltage to the transformer. Thus, the terminals to be connected to a voltage may be DC terminals or AC terminals as well.

The specified transformer is not limited to the examples shown. For example, the primary and secondary sides can be interchanged.

What is claimed is:

1. A piezoelectric transformer comprising:
a base body comprising a piezoelectric material that is polarized in an input region of the base body along a first axis and in an output region of the base body along a second axis perpendicular to the first axis;
wherein a polarization of the piezoelectric material in a transition region between the input region and the output region gradually changes its direction from a polarization along the first axis to a polarization along the second axis.

2. The piezoelectric transformer according to claim 1, further comprising first and second input electrodes disposed adjacent the input region and at least one output electrode disposed adjacent the output region, wherein ends of the input electrodes of one polarity facing the transition region have a smaller distance from the output electrode than the ends of the input electrodes of another polarity.

3. The piezoelectric transformer according to claim 2, wherein the input region comprises a plurality of internal electrodes provided as the input electrodes; and
wherein the output region includes only one external electrode that is provided as the output electrode.

4. The piezoelectric transformer according to claim 3, wherein the input electrodes are arranged in the base body, and wherein the output electrode is arranged over the base body surface.

5. The piezoelectric transformer according to claim 4, wherein the difference between the distances of the input electrodes of different polarities from the output electrode is greater than the distance between two adjacent input electrodes.

6. The piezoelectric transformer according to claim 2, wherein the difference between the distances of the input electrodes of different polarities from the output electrode is greater than the distance between two adjacent input electrodes.

7. The piezoelectric transformer according to claim 2, further comprising a ground connection coupled to the input electrodes, wherein the input electrodes are connected to the ground connection with the shorter distance to the output electrode.

8. The piezoelectric transformer according to claim 2, further comprising a voltage generator that includes a ground, wherein the input electrodes with the shorter distance to the output electrode are connected to the ground of the voltage generator.

9. The piezoelectric transformer according to claim 8, wherein the voltage generator generates a voltage of the same polarity as the voltage used for polarizing the transformer.

10. The piezoelectric transformer according to claim 9, further comprising a rectifier with an output voltage that has a polarity that is the same as the polarity of the voltage used for polarizing the output part, the rectifier being connected to the output electrode.

11. A method of operating a piezoelectric transformer, the method comprising:
providing a piezoelectric transformer comprising a base body comprising a piezoelectric material that is polarized in an input region of the base body along a first axis and in an output region of the base body along a second axis perpendicular to the first axis, wherein a polarization of the piezoelectric material in a transition region between the input region and the output region gradually changes its direction from a polarization along the first axis to a polarization along the second axis; and
connecting input electrodes of the piezoelectric transformer to a ground of a voltage generator.

12. The method according to claim 11, wherein the voltage generator generates a voltage of the same polarity as a voltage used for polarizing the piezoelectric transformer.

13. The method according to claim 11, further comprising connecting a rectifier, whose output voltage has a polarity that is the same as the polarity of the voltage used for polarizing the output part, to the output electrode.

14. The method according to claim 11, wherein the piezoelectric transformer further comprises first and second input electrodes disposed adjacent the input region and at least one output electrode disposed adjacent the output region, wherein ends of the input electrodes of one polarity facing the transition region have a smaller distance from the output electrode than the ends of the input electrodes of another polarity.

15. The method according to claim 14, wherein connecting input electrodes to a ground of a voltage generator electrodes comprises connecting the input electrodes with the shorter distance to the output electrode to the ground of the voltage generator.

16. The method according to claim 15, wherein the voltage generator generates a voltage of the same polarity as a voltage used for polarizing the piezoelectric transformer.

17. The method according to claim 15, further comprising connecting a rectifier, whose output voltage has a polarity that is the same as the polarity of the voltage used for polarizing the output part, to the output electrode.
